(19) United States
(12) Patent Application Publication
(10) Pub. No.: US 2005/0067007 A1
(43) Pub. Date: Mar. 31, 2005

(54) Photovoltaic element and production methods

(76) Inventor: Nils Toft, Malmo (SE)

Correspondence Address: FISH & RICHARDSON PC, 225 FRANKLIN ST, BOSTON, MA, 02110, US

(21) Appl. No.: 10/494,560

(22) PCT Filed: Aug. 11, 2002
(86) PCT No.: PCT/SE02/02049

(30) Foreign Application Priority Data
Nov. 8, 2001 (SE) 0103740-7

(51) Int. Cl. H01L 25/00

(52) U.S. Cl. 136/245; 136/244

(57) ABSTRACT

The present invention relates to a flexible photovoltaic element and a method of manufacturing the same. The photovoltaic element (100b, 200, 300, 400, 500, 1000, 1100) comprises at least two covering layers (101b, 106b, 722a, 722b) and a semi-material consisting of at least two electrode layers (102b, 105b, 2012, 2063, 3011, 3062, 4062) and at least one electrolyte carrier layer (104b, 208, 308, 408, 1003). The element is composed of laminated and/or extrusion coated assembly of said at least two covering layers and said semi-material, and that said covering layers encapsulate said semi-material.

### TECHNICAL FIELD OF THE INVENTION

The present invention relates to a photovoltaic element, preferably used as a solar cell or the like and most preferably a flexible photovoltaic element of the Grätzel solar cell type and a novel method for continuous production of the same.

### BACKGROUND

Dye Photovoltaic Solar Cell (“Grätzel-cell” or Dye PV cell) is a new kind of solar cell, which is currently being developed towards commercialisation. The Grätzel Cell converts solar radiation into electricity with remarkable efficiency exceeding 10% under standard AM 1.5 sunlight. In a Grätzel cell, a photovoltaic cell comprises a light transmitting electrically conductive layer deposited on a glass plate or a transparent polymer sheet to which a series of titanium dioxide layers have been applied, in which at least the last titanium dioxide layer (optionally also the second to last and third to last layer) are doped with a metal ion which is selected from a divalent or trivalent metal

In an enhanced version, as in U.S. Pat. No. 5,482,570, for example, which relates to a photovoltaic cell comprising a substrate having a support face having a first electrode thereon and a second electrode spaced from the first electrode by a plurality of layers including at least one layer of a semiconducting material with an active junction interface thereat, said active junction having a developed surface area greater than its projected surface area.

WO 99/66519 describes a method for manufacturing a photovoltaic element comprising a layered structure of at least a first electrically conductive layer, a layer of crystalline metal oxide semiconductor material deposited thereon, a second electrically conductive layer and an electrolytic liquid between the layer of semiconductor material and the second electrically conductive layer, wherein at least one of the electrically conductive layers is transparent and is deposited on a transparent substrate, comprising of (i) providing a layer of crystalline metal oxide semiconductor material on a first electrically conductive layer and providing an electrically conductive layer; (ii) arranging an edge zone of a thermoplastic adhesive material round the deposited layer of semiconductor material; (iii) arranging the second respectively the first electrically conductive layer over said edge zone; (iv) locally heating at least a first part of the edge zone and simultaneously exerting pressure locally on the surface of this first part to cause the adhesive to adhere to the first and second conductive layer in order to form a partially bounded space; (v) introducing an electrolytic liquid into said space, wherein the second electrically conductive layer is spatially separated by this liquid from the layer of semiconductor material; and (vi) locally heating the remaining part of the edge zone not yet heated in the fourth step and simultaneously exerting pressure locally on the surface of this remaining part to cause the adhesive to adhere to the first and second conductive layer and to enclose the liquid.

According to an enhanced method (by M. Sp\overline{a}th, J. M. Kroon, P. M. Sommeling, J. A. Wienke, J. A. M. van Roosmalen Netherands Energy Research Foundation ECN, and T. B. Meyer, A. F. Meyer, O. Kohle Solaronix S. A.), the working principle of a nano-crystalline dye sensitised solar cell (nc-DSC) of the Grätzel type depends on a working cycle consisting of dye excitation, electron injection into titanium dioxide and fast reduction of the oxidized dye by a redox couple. New design concepts of low and high power applications, introduced conform to market requirements, have resulted in a working nc-DSC plastic cell. A new sealing and interconnection technique is introduced which is suitable for nc-DSC high power applications.

In EP 1 087 412 is provided an electrolyte composition, comprising an electrolyte containing at least one kind of an imidazolium salt selected from the group consisting of 1-methyl-3-propyl imidazolium iodide, 1-methyl-3-isopropyl imidazolium iodide, 1-methyl-3-butyl imidazolium iodide, 1-methyl-3-isobutyl imidazolium iodide and 1-methyl-3-sec-butyl imidazolium iodide, a halogen-containing compound dissolved in the electrolyte, and a compound dissolved in the electrolyte and containing at least one element selected from the group consisting of N, P and S, the compound being capable of forming an onium salt together with the halogen-containing compound.

WO 99/66519 discloses a method for manufacturing a photovoltaic element comprising a layered structure of at least a first electrically conductive layer, a layer of crystalline metal oxide semiconductor material deposited thereon, a second electrically conductive layer and an electrolytic liquid between the layer of semiconductor material and the second electrically conductive layer, wherein at least one of the electrically conductive layers is transparent and is deposited on a transparent substrate, comprising of (i) providing a layer of crystalline metal oxide semiconductor material on a first electrically conductive layer and providing an electrically conductive layer; (ii) arranging an edge zone of a thermoplastic adhesive material round the deposited layer of semiconductor material; (iii) arranging the second respectively the first electrically conductive layer over said edge zone; (iv) locally heating at least a first part of the edge zone and simultaneously exerting pressure locally on the surface of this first part to cause the adhesive to adhere to the first and second conductive layer in order to form a partially bounded space; (v) introducing an electrolytic liquid into said space, wherein the second electrically conductive layer is spatially separated by this liquid from the layer of semiconductor material; and (vi) locally heating the remaining part of the edge zone not yet heated in the fourth step and simultaneously exerting pressure locally on the surface of this remaining part to cause the adhesive to adhere to the first and second conductive layer and to enclose the liquid. This invention does not concern structural concept according to the present invention. Moreover, this invention does not allow or suggest a continuous manufacturing method according to the present invention.

### SUMMARY

The main object of the present invention is to provide a manufacturing process for continuous production of flexible photovoltaic elements, e.g. used in solar cells, and a photovoltaic element for making solar cells.

In addition to the eminent increase of the productivity and possibility to use cheap raw material, the invention provides a number of advantages:
Possibility to produce substantially endless long cells, and maintaining the functionality of the cells while combining flexibility of the cells with large continuous areas of the cells
Simplified production process such as elimination of a separate sealing step, as the sealing is achieved automatically during lamination, and elimination of the need to apply electrolyte before or during sealing,
Simplified production process, as contacting of cells in series can be automatically integrated in the process
Possibility of employing specially effective material,
Possibility of using a range of different material,
Rollable materials and rollable cells,
New applications,
Using non-polluting material,
Flexibility of the cells allows easily foldable, more easily transportable and more easily storable end-products,
Possibility to adjust at least one of the parameters current or voltage in a simple way,
Suitable for light poor environment, such as indoors use or cloudy areas.

The invention also suggests using a spacer layer that can be adhered to surrounding layers, which makes it possible to achieve adhesion between all layers in the laminate, and at the same time to create space for the electrolyte and to avoid any contact between the lower electrode and the TiO₂-layer.

The invention also suggests, besides PET, to use (a variety of) other transparent or semi-transparent thermoplastic materials, such as PE/m-LLDPE or PA, PP etc. For example, using m-LLDPE generally gives better encapsulation, better moisture barrier and is more cost efficient than PET.

Suitable polymers may be chosen partly depending on the intended use of the final cell-structure (e.g. indoor-/outdoor use, humidity). Polymers used within the cell-structure may be UV-stabilised.

The invention also suggests to coat surfaces within the cells and outside the cell with SiOₓ, hereby achieving several advantages, among others oxygen barrier and passivisation (i.e. for avoiding galvanic effects or various chemical reactions).

Thus, further advantages are:
by using heat-resistant (i.e. a material which resists, e.g. sintering at about 450° C.) substrate for the TiO₂, it is possible to sinter TiO₂ at high temperature, which gives better function,
by using heat-resistant substrates for the TCO, it is possible to use SnO₂ as TCO (Transparent Conductive Oxide), which gives better function,
by using certain spacer layers, adhesion can be achieved against surrounding layers,
using PE, is more cost efficient and gives better moisture barrier than PET,
using m-LLDPE gives very good sealability and less risk for leakage, and
by coating surfaces with SiOₓ, among other advantages, better oxygen barrier and passivisation of surfaces is achieved.

Other advantages of the method(s) and the photovoltaic element(s) according to the invention are disclosed in the following description.

For these reasons a flexible photovoltaic element is provided, according to the invention, comprising at least two covering layers and a semi-material consisting of at least two electrode layers and at least one electrolyte carrier layer. The element is composed of at least two covering layers and a semi-material joined together through at least one extrusion coating and/or lamination operation of said two covering layers and said semi-material, said covering layers encapsulating said semi-material. Preferably, the element further comprises at least one layer of substantially flexible and heat-resistant substrate, which allows sintering process in high temperatures. This is of substantial importance for allowing simplified manufacturing steps of the element. The substrate is provided with substantially semi-conducting characteristics, laminated in said semi-material. In one embodiment, at least one of said electrode layers comprises of a polymeric material applied with a TCO (Transparent Conductive Oxide). The substrate can be applied with a semi-conducting material. Preferably, at least one of said electrode layers consists of a screen structure applied with a semi-conducting material. In one embodiment, at least one electrode layer consists of a substantially flexible and heat-resistant material applied with a semi-conducting material. In another embodiment, at least one electrode layer consists of a wire-screen applied with a semi-conducting material. Preferably, at least one of said electrode layers is perforated. In yet another embodiment, one electrode layer is arranged as a bottom layer and applied with a catalyst. Preferably, the semi-conducting material is applied with a dye. Between said electrode layers a spacer structure can be arranged.

The polymeric material may consist of one of PE, PET, PP or PA, said substantially flexible and heat-resistant material can consist of glass-fibre and said screen structure consists of glass-fibre or of textile. In one embodiment, the wire-screen consists of a conductive material. The TCO may consist of SnO₂. The semi-conducting material may consist of TiO₂. Preferably, electrolyte comprises potassium iodine or an iodine solution. The element comprises a layer of polymer coated with TCO, a substrate provided with TiO₂ and a dye, a spacer provided with electrolyte and a layer of polymer coated with TCO and catalyst. At least one of said covering layers is substantially transparent, and consists of a single- or multilayer structure, comprising one or more of the following: PE-layer(s), PP-layer(s), PET-layer(s), tie-layer(s), ionomer layer(s), EAA-layer(s), EMAA-layer(s), PA-layer(s), EVOH-layer(s), SiOₓ-layer(s). In one embodiment, the layers in said semi material and covering layers are provided with partial adhesion between all layers prior to application of covering layers and sealing.

Preferably, in one embodiment, the photovoltaic element further comprises at least two heat-resistant layers, where two of the layers either constitute electrodes or constitute a substrate for electrode layers, and that at least one of the heat-resistant layers constitute substrate for an at least one semi-conducting layer. Preferably, at least one of said electrode layers is provided as a covering layer.

Most preferably, said layers are supplied continuously before said extrusion coating and/or lamination operation. The element is a Grätzel-cell. For electrical connection, conductive materials are applied on the outside of the cells, thereby electrically connecting the electrodes of separate cells.

According to one embodiment the electrodes, may consist of perforated metal-foil or metal-screen which can be metallized with a layer of another metal in order to be more “inert” towards the electrolyte. According to another embodiment, the polymer-based substrates may be metallized in order to achieve conductivity and thus may be used as electrodes by perforation if used as upper electrode. According to one embodiment, the electrolyte-impregnated spacer layer, e.g. paper or foamed polymer, may be laminated into cells, which can be used in applications in which adhesion between layers is not necessary. Hereby the injection step can be avoided.

The invention also relates to a method of producing a flexible photovoltaic element, the method comprising the steps of: providing a semi-material consisting of at least two electrode layers and at least one electrolyte carrier layer, providing at least two covering layers, joining together said at least two covering layers and said semi-material through at least one extrusion coating and/or lamination operation for composing said element, whereby said covering layers encapsulate said semi-material through said extrusion coating and/or lamination operation. Preferably, said at least two covering and electrode layers and at least one electrolyte carrier layer are supplied continuously. The method further comprises the step of providing at least one layer of a heat resistant substrate and/or a spacer layer before lamination. The method also comprises the step of providing said substrate with TiO₂. The method also comprises an injection step of an electrolyte in said electrolyte carrier layer. Preferably, the substrate and/or a spacer layer is said electrolyte carrier. The method also comprises cutting cell structure into smaller cell units. Preferably, the method is speeded by producing said electrode layers in a second parallel process.

The injection step comprises the steps of: arranging a hole during the lamination in a bottom sealing film, injecting by an injector under a pressure the electrolyte through the hole, the electrolyte filling a spacer and some of the bottom electrode and the substrate due to capillary forces, and arranging a thin film over said hole and melting it together with the film. The method also comprises the steps of: providing a through hole through the cell layers, filling said hole with electrolyte, which is distributed to the spacer, and providing a sealing with riveting or by thin films applied on each side of the laminate. The covering means is a film or foil. The method also comprises rolling said substrate together with said heat-resistant spacer layer, which prevents contact between the rolled up substrate layers and allows for hot air to pass between the substrate layers. Said roll is exposed to hot air, e.g. by being inserted into an oven, where in a drying and sintering of TiO₂ is performed.

### BRIEF DESCRIPTION OF THE DRAWINGS

In the following, the invention will be further described in a non-limiting way under reference to the accompanying drawings in which:

FIGS. 1a and b are schematic cross-sectional views illustrating a part of a conventional photovoltaic element and an element according to the present invention, respectively,

FIG. 2 illustrates in a schematic way a first production process alternative according to the present invention,

FIG. 3 illustrates in a schematic way a second production process alternative according to the present invention,

FIG. 4 illustrates in a schematic way a third production process alternative according to the present invention,

FIG. 5 illustrates in a schematic way a fourth production process alternative according to the present invention,

FIG. 6 illustrates in a schematic way an alternative sequential production process according to the present invention,

FIG. 7A illustrates in a schematic way a detailed production process alternative according to the present invention,

FIG. 7B illustrates in a schematic way a detailed production process alternative according to the present invention,

FIG. 8 illustrates in a schematic way a part of the production process according to the present invention,

FIG. 9 illustrates in a schematic way another part of the production process according to the present invention,

FIG. 10 illustrates in a schematic way cross-section of electrolyte filling steps in one element according to the present invention,

FIG. 11 shows schematic views illustrating alternative end-products for solar cells produced according to the invention,

FIGS. 12-14 show different process steps, and

FIGS. 15a, 15b, 15c schematically illustrate a multi-lane laminate structure production.

### DETAILED DESCRIPTION OF THE EMBODIMENT

The main idea of the present invention is to present a method for mass production of flexible solar cells, such as Grätzel cells, and construction of flexible polymer-based cells. The manufacturing process can be compared to, e.g. packaging lamination technique. The invention also comprises using a combination of special type of materials, which allows the special and continuous production process different from the prior art technique.

Moreover, main principle of one variant of the production method is to separately produce flexible, continuous electrode layers, semi-conducting layer and in some cases a spacer layer, and heat laminate/extrusion coat the layers together with various polymer films into a flexible and continuous laminate (semi-material), which is cut into pieces and laminated in-between two films or a film and a foil, whereby the pieces are encapsulated and thereby sealed cells are produced. If the semi-material does not contain electrolyte (e.g. as a gel), the electrolyte is injected in the cells after sealing. By using this principle, the following advantages are achieved:
separate production of the different layers allows for parallel process steps, which is time saving,
production of continuous layers speeds up the process,
heat lamination/extrusion coating of the continuous layers into a laminate (semi-material) gives the possibility for adhesion between layers, which makes it possible to cut the laminate Into pieces and use the pieces in next process steps. Adhesion between layers also allows for producing flexible cells with larger areas, without loosing contact between layers,
cutting the laminate (semi-material) into pieces, gives flexibility to adjust size of cells late in process,
sealing of the cells by encapsulation between two outer layers (in some cases followed by injection of electrolyte) significantly simplifies the sealing and filling operation of the cells, and
sealing of the cells by encapsulation between two outer layers gives possibility for wider and more reliable sealing

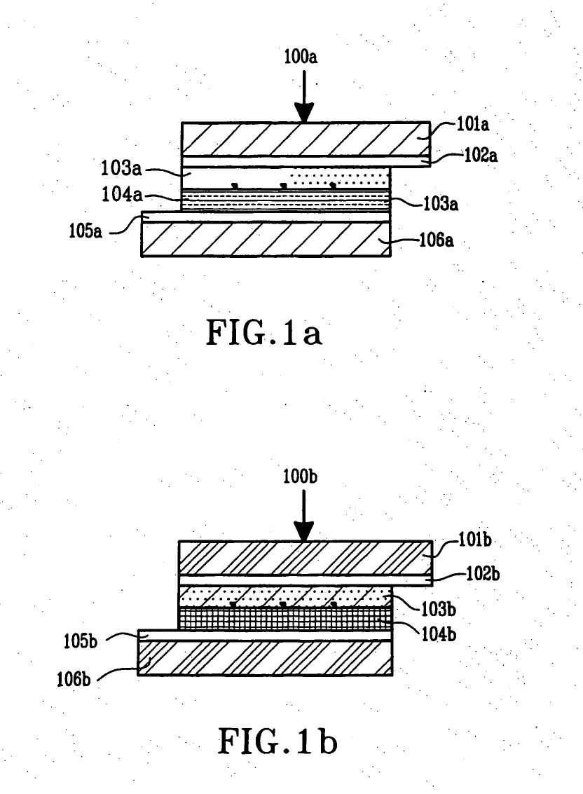

FIGS. 1a and 1b show cross-sections through two cells for illustrating the differences between a conventional Grätzel cell element and an element produced according to the invention. FIG. 1a is a Grätzel cell element 100a and FIG. 1b a cell element 100b made according to one aspect of the present invention.

The conventional cell element 100a comprises a layer 101a of glass, provided with SnO₂, constituting the electrode layer 102a, a layer 103a of TiO₂ sensitised with a dye, an electrolyte layer 104a and a layer 106a of glass provided with SnO₂, constituting the electrode layer 105a, and catalyst.

The exemplary cell element 100b according to the invention comprises a layer 101b of polymer coated with TCO, where the TCO, i.e. layers of 102b and 105b constitutes the electrodes, a substrate 103b provided with TiO₂ (or other semi-conducting material) and sensitised with a dye, a spacer 104b provided with electrolyte and a layer 106b of polymer,-coated with TCO and catalyst, or conductive foil. Application of TiO₂ on a heat resistant substrate allows flexibility and provides better efficiency and capacity.

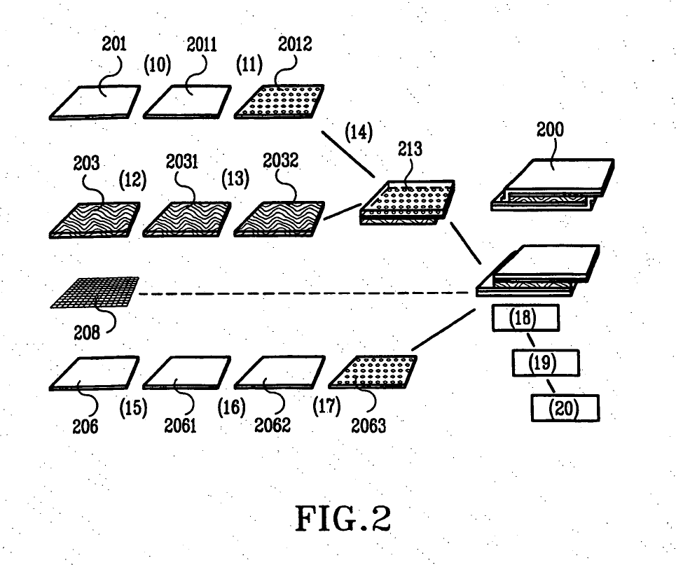

FIG. 2 is a schematic illustration over the production steps according to one exemplary embodiment. Steps shown in parallel can be conducted in parallel. In a first step (10), a polymer film 201 constituting one face of the cell structure is coated with TCO. The coated polymer film 2011 is then perforated (11) to a perforated layer 2012. A substrate 203 made of a heat-resistant material is impregnated with a TiO₂-solution and sintered in a first step (12) and sensitised with a dye in a second step (13) to build a substrate layer 2032.

The first layer 2012 and the second layer 2032 are then joined, as a third layer is applied on top of the first layer 2012 by extrusion coating or heat lamination (14) to a package 213. Also, the second face 2063 of the cell structure comprising a polymer film 206 is provided (15) with TCO 2061, provided (16) with a catalyst 2062 and perforated (17). The second face structure is joined with the package 213, as an additional layer is extrusion coated or heat laminated at the outside of the second face structure with a spacer 208 between the package 213 and the second face 2063, building the cell structure 200. The dye sensitisation can be done after step (14) to prevent harming the dye.

As it appears from the drawing, the packages 213 and 2063 are displaced relative each other, which allows sealing of the edges in the machine direction during step (43) and (46). Otherwise, the sealing in the machine direction and in the cross-direction is performed in the final lamination step (19), after cutting (18). Finally, the encapsulated cell structure is injected with electrolyte (20).

Using (a) heat-resistant substrates for the TiO₂ and for the TCO, which preferably consists of glass-fibre, has many advantages, amongst others it allows:
Connection of the substrate and the electrodes by heat lamination/extrusion coating, which opens up possibilities for the unique, continuous process, as the TCO is not applied directly on the outer layers of the cell-structure,
Sintering of TiO₂ in high temperature (e.g. 450° C.),
Using SnO₂ as TCO,
Using different materials, such as m-LLDPE for sealing layer and barrier layers, which in turn yields better sealing, less risk for leakage, lower moisture permeability and also cheaper production,
Production of substantially endless cells, enabling cells with large area and multi (two) step processes, which in turn allows automatic and wider sealing,
Adhesion between the layers,
Parallel production process steps, allowing faster, more effective and cheaper processes.

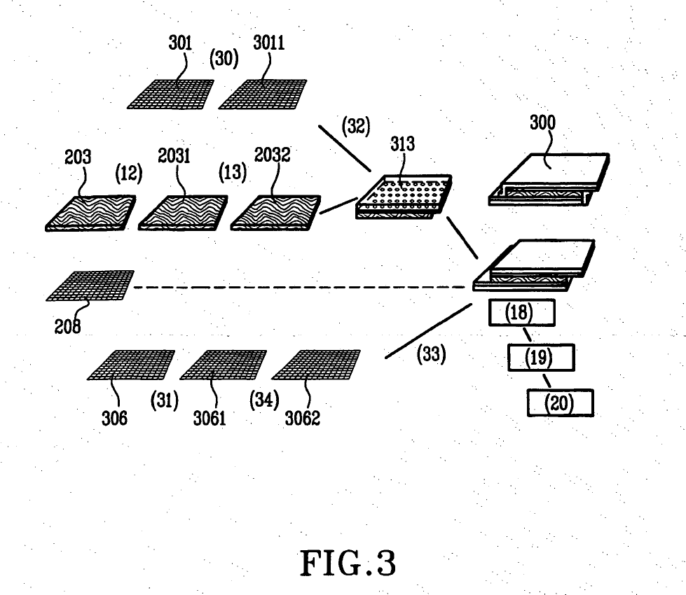

FIG. 3 illustrates an alternative production process. Reference signs for parts and steps same as FIG. 2 refer to similar parts and process steps. In this case, the polymer film is substituted with a screen 301 and 306, e.g. made of polymer, heat resistant textile, glass fibre, carbon fibre or metal treated/coated for non-galvanic effects. The screen is provided (30), (31) with, e.g. SnO₂, constituting the electrode layers 3011 and 3062. The bottom layer 3062 is also provided (34) with a catalyst. If non heat resistant substrate is used, other TCO than SnO₂ should be used, such as ambient temperature sputtered Indium Tin Oxide (ITO). The electrode layer 3011 is joined with the substrate 2032 and the electrode layer 3062 is joined with the package 313 by extrusion coating or heat lamination (32, 33) of a polymer layer on the electrode sides. Between the package 313 and the electrode layer 3062, a spacer layer 208 can be applied during the extrusion coating or heat lamination operation (33).

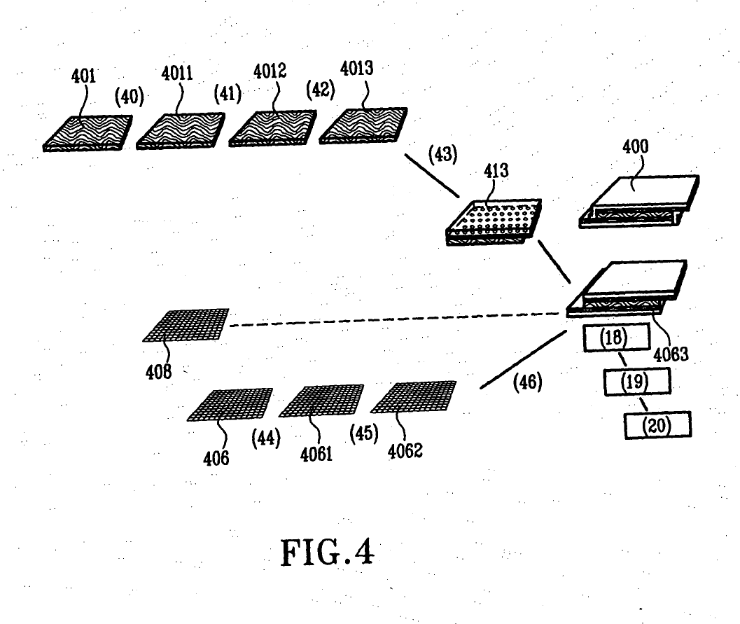

The remaining process steps are substantially the same as described in connection with FIG. 2. The electrolyte used may comprise potassium iodine or an iodine solution. Another alternative method is illustrated in FIG. 4. In this case, the first top layer 413 comprises a substrate of heat-resistant layer 401, e.g. made of glass-fibre, provided with TCO, e.g. SnO₂, or perforated metal-foil, which may be SiOₓ-coated and provided with TCO, e.g. SnO₂, in a first step (40), provided and sintered with TiO₂ in a second step (41) and finally sensitised with a dye in a third step (42). A polymer layer is extrusion coated or heat laminated (43) on the top of the layer to constitute layer 413. In case of using perforated, heat-resistant films or foils as upper electrode or substrate for upper electrode, the TiO₂ is applied on the side of the electrode, facing the light-source.

The bottom layer 4063 comprises a screen of heat-resistant material 406, such as glass-, or metal-foil, which may be SiOₓ-coated and coated (44) with SnO₂, and provided (45) with a catalyst and extrusion coated or heat laminated (46) with a polymer layer to constitute the cell structure 400. Between the package 413 and the electrode layer 4062, a spacer layer 408 can be applied during the extrusion coating or heat lamination operation (46). Further production steps (18-20) are performed as described above in connection with FIG. 2.

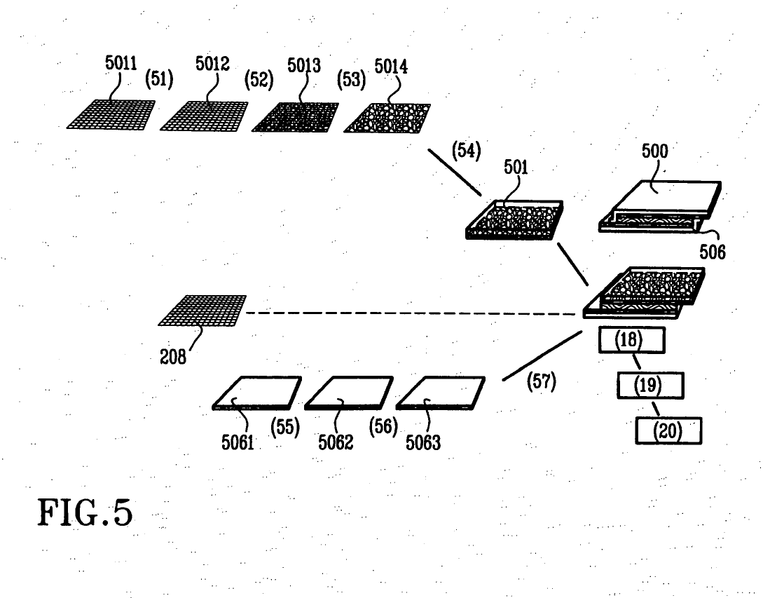

In another alternative process, as illustrated in FIG. 5, the top layer 501 comprises a wire-screen 5011, e.g. made of conductive material which may be SiOₓ-coated and may be coated with SnO₂ 5012 in first step (51) and then provided and sintered with TiO₂ 5013 in a second step (52), thereafter it is sensitised with a dye 5014 in a third step (53). Finally, the layer 5014 may be extrusion coated or heat laminated (54) with a polymer layer.

The bottom layer 506 comprises a conductive substrate 5061, such as a metal foil, which may be provided with SnO₂ 5062 in a first step (55) and provided with a catalyst 5063 in a second step (56) before it is extrusion coated or heat laminated (57) with a polymer layer. The remaining steps are similar to the described method in conjunction with FIG. 2.

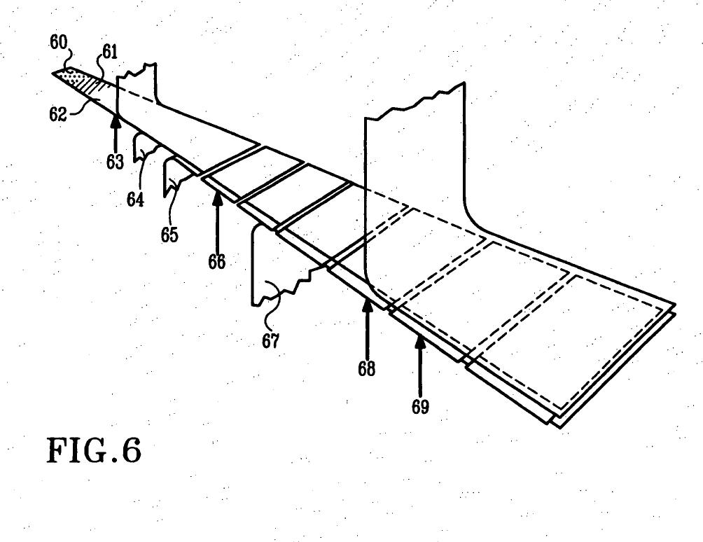

FIG. 6 illustrates the sequential production of a solar cell according to one alternative of the invention. In a first step (60) a heat-resistant 722a, 722b is provided, which is coated or impregnated (61) with TiO₂ and sintered. In step (62) the sintered substrate is sensitised with a dye. Electrode layers produced in parallel processes are then provided and heat laminated (with or without an additional, extrusion coated polymer layer) in step (63) and (65), while the spacer is arranged before lamination in step (64). The continuous cell structure is then cut in smaller cell units in step (66). Top and bottom films are provided and heat laminated to cell units in steps (67) and (68) before injection with electrolyte at step (69). The film in step (68) may be extrusion coated.

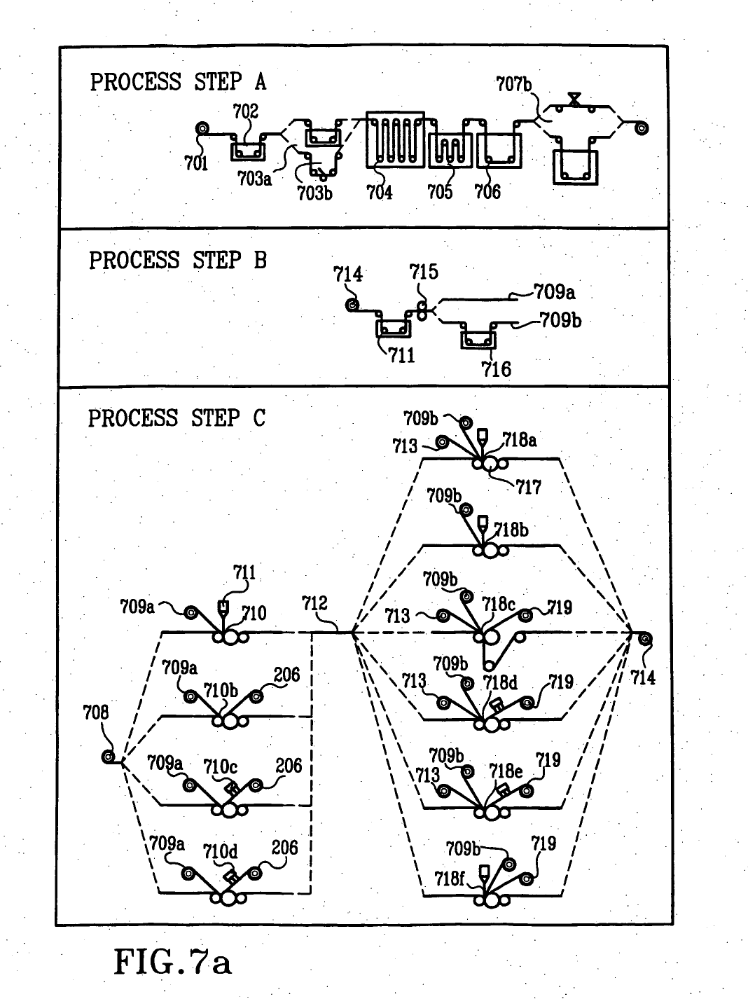

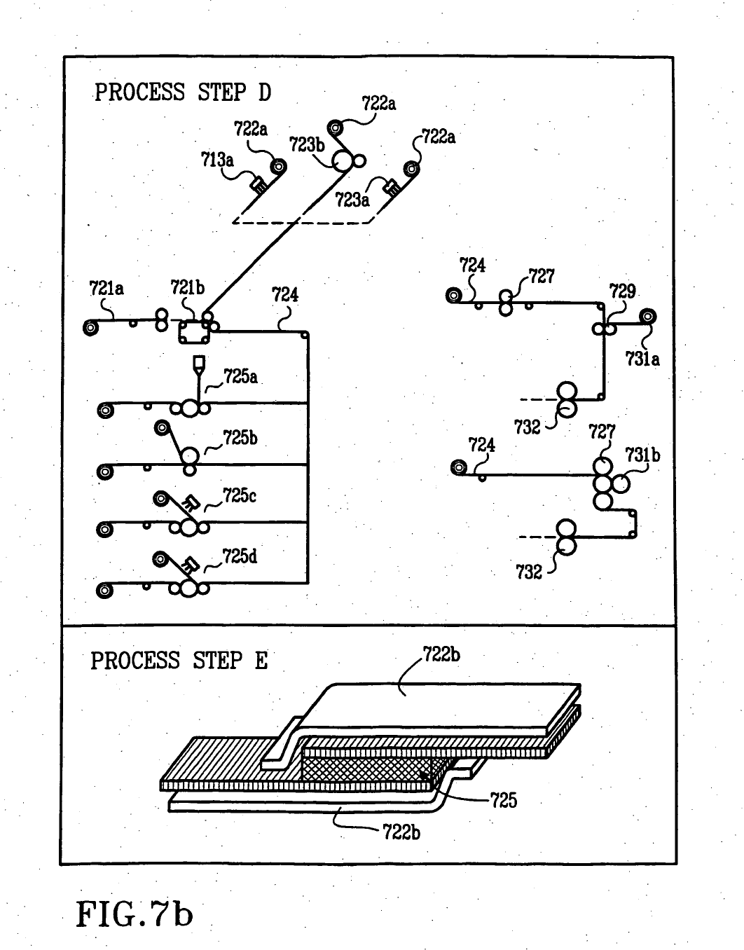

A more detailed production process is illustrated in FIGS. 7A and 7B. The reference signs in the description refer to the encircled reference signs in the drawings.

In process step A, a flexible, heat-resistant substrate, of types mentioned above, which can be surface treated is rolled off a cylinder 701 and may be passed through a process step 702 in which a thin layer of TCO, i.e. SnO₂, is applied. Then 703 is provided with TiO₂, e.g. dissolved in ethanol or it is coated 703b with paste of TiO₂ before it is dried. The substrate is dried in an oven 704, which sinters it at about 450° C. for some hours (e.g. 3-4 h). During the sintering the substrates is moved slowly up and down between cylinders. The substrate after the bath is passed through a dye bath 705 and then a water bath 706 and an ethanol bath 707a. It may also be sprayed 707b with ethanol. Finally, the substrate 708 is rolled on a cylinder, for storage in an air-proof and dark compartment until it is needed for next process step. Instead of passing through different baths the materials can be sprayed onto the surfaces.

An alternative way (alternative to process step 704) to sinter the TiO₂, applied on a substrate, may be to roll up the coated substrate on a roll together with a heat resistant spacer layer (e.g. a screen), which hinders contact between the rolled up substrate layers and allows for air to pass between the substrate layers. Thereafter the roll may be exposed to hot air, e.g. put into an oven, where the drying and sintering of the TiO₂ is taking place.

In the parallel process step B, electrodes 709 are produced (upper electrode, 709a and lower electrode, 709b). A substrate 714 is applied 711 with a TCO. If the substrate 714 is heat resistant, the TCO may be SnO₂. Non-heat resistant substrates may be for example a transparent, flexible polymer film and heat resistant substrates may be a screen structure, made of glass-fibre, heat resistant polymer or textile. If the substrate is a film, perforation is done in step 715. If the electrode is going to be used as lower electrode (709b) it is additionally provided with a thin layer of catalyst in step 716.

In process step C the lamination is carried out. In first lamination, the top electrode 709a (polymer film, screen, heat resistant or non-heat resistant substrate, with or without a layer of TCO) is laminated with the substrate 708. It is carried out in a nip 710, either by extrusion coating 711 a polymer on the outside of the top electrode or by heat laminating the polymer film 206 on the outside of the top electrode 709a. In the latter case either a hot cylinder nip 710b or exposure to heat, e.g. by means of IR heater 710c, flame/burner 710d or other heating source, is used. The polymer film may have a thermoplastic adhesive layer, e.g. of ionomer, EM or EMAM facing the heat source. This can be used in any of above described embodiments for creating necessary conditions for later edge-wise sealing in the coming lamination step. In case the spacer screen is used in the cell structure and it is going to be laminated in the structure in the second lamination (see below) and no adhesion is wanted between layers within the laminate 714, the external layers are extrusion coated/heat laminated in first and second laminations, in such way that they overlap the structure and automatically produce alongside sealing.

The second lamination means that the laminate 712 is (according to above) laminated with the bottom electrode 709b.

The second lamination is carried out in a nip 717, where the laminate 712 exposed to heat is laminated to the bottom electrode 709b, possibly with a spacer 713, e.g., made of a flexible, insulating layer through which an electrolyte can pass, such as polymer screen, textile, paper, (polymer coated) glass fibre screen, SiOₓ- or polymer coated metallic screen. In order to better adhere to surrounding layers, the spacer screen may be impregnated or primed with a thin priming layer, which may consist of a thermoplastic polymer. The spacer may also comprise of porous perforated paper. The heat can be provided by extrusion coating 718a the polymer outside the bottom, electrode 709b and in that way adhering the layers to each other. If no spacer is used, the substrate and the bottom electrode are laminated together directly, in which case heat is provided by extruding 718b the polymer outside the bottom electrode; thus, the bottom electrode is penetrated and mechanical adhesion to substrate is generated. Alternative lamination may include heat supply in a hot cylinder nip 718c, where a cold polymer film 719 is heat laminated outside the bottom electrode (with or without spacer), or heat lamination on the outside of the bottom electrode through other heating of the polymer film 719, e.g. by means of a heating source 718d or flame/burner 718e. The polymer film may have a thermoplastic adhesive layer of e.g. ionomer, EM or EMAA facing the heat source. Another alternative is to substitute the spacer 713 with a foamed polymer having open cells, which is extruded 718f between the substrate and the bottom electrode with or without cold polymer film on the outside of the electrode 709b.

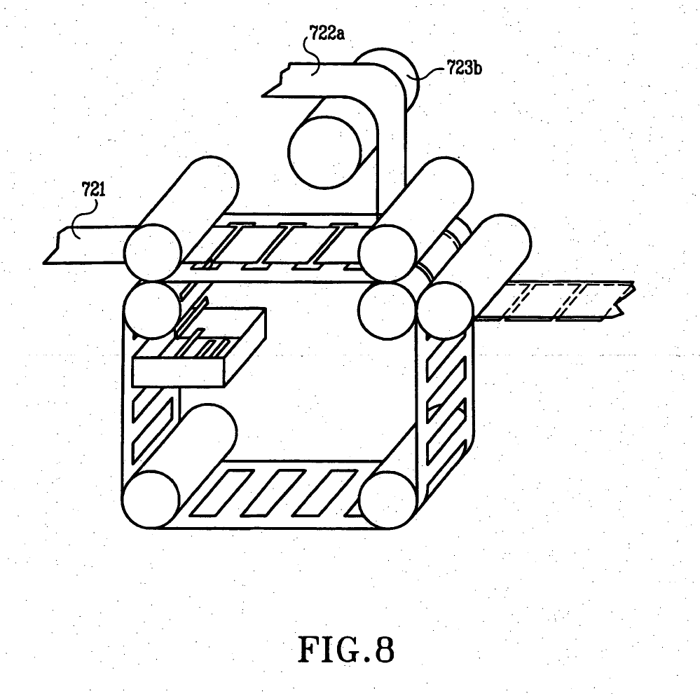

According to FIG. 7B, the process step D includes cutting laminate 721a in smaller portions 721b. See also FIG. 8. These portions are then placed in equal distance with bottom side on a polymer film 722a exposed to heat. The heat exposure is carried out by means of flaming 723a, hot cylinder nip 723b or other heating source 723c. Alternatively, the portions are positioned between two, polymer film portions 722b and sealed 725 through pressure and heat or other sealing technology. The polymer film 722a or 722b can be made of, for example PE (or another transparent thermoplastic polymer), but due to high oxygen blocking demands a co-extruded structure, e.g. a five layer structure PE/tie/EVOH/tie/PE 723b or PE/tie/PA/tie/PE 723c or a structure comprising a SiOₓ-layer 723d should be used. The film with laminate parts 724 are then guided to a cylinder nip 725, where it is coextrusion coated 725a with hot extruded polymer e.g. a five layer structure PE/tie/EVOH/tie/PE or PE/tie/PA/tie/PE or heat laminated in a hot cylinder nip 725b, or with a flame/burner 725c or with another heating source 725d, with a cold polymer film, e.g. a five layer structure PE/tie/EVOH/tie/PE 723b or PE/tie/PA/tie/PE 723c, or a structure comprising a SiOₓ-layer 723d.

An alternative way to perform process step D may comprise two steps of extrusion coating. In this case, the polymer film 722a is only used as a carrier of the portions 721b, adhered onto the surface of the polymer film 722a, which does not take part in alongside sealing of the cells. After adhering the film portions 721b on the carrier film 722a, extrusion coating (725a) is performed in two steps, according to previous description, sealing the cells by encapsulation, whereby the cells are sealed on all four sides, letting the electrodes pass through the alongside seals.

Yet another way to perform process step D is to proceed according to the latter description, but instead of extrusion coating the covering layers, they may be extrusion laminated (i.e. cold polymer films are adhered to the film portions 721b by extruded hot polymer films, applied in-between the cold polymer films and the film portions).

All polymer films mentioned above, which are used as covering layers (722a, 722b and polymer films applied in steps 725a-d), and which are intended to seal to other materials, may have a layer of thermoplastic adhesive polymer, e.g. ionomer, EAA or EMM, facing the side to be sealed, and all PE-layers may be substituted with other thermoplastic polymers, e.g. with PET-layers. The polymer films may not only consist of five-layer structures, they may consist of one or more layers. E.g. by using two-layer structures, one of the layers may be a thermoplastic adhesive polymer (e.g. ionomer), and the other layer in the two-layer structure may be a polymer (e.g. PE) different from the polymer (e.g., PET) in the layer to be sealed against.

In the final process step, i.e. step E, the electrolyte, e.g. consisting of potassium iodine-iodine solution, is injected 727 in the laminate portions 724. This is done by means of, e.g. rotating cylinders (described below) having injection nozzles. The injection is done in the spacer layer. It is also possible to add the electrolyte before the sealing. Eventually, the injection openings are sealed 729 with a film 731a or hot-melt 731b and pieces may be cut 732.

All the laminated films can be surface treated, for example through flame treating or corona, to create better conditions for adhesion. Moreover, all films or screens coated by SnO₂ or working as the exterior of the cell or in contact with the electrolyte may be coated with SiOₓ. Additionally, all metal-foils used as electrodes may as earlier described be coated with SiOₓ and then with TCO, e.g. SnO₂, but may also be uncoated, if certain metals are chosen.

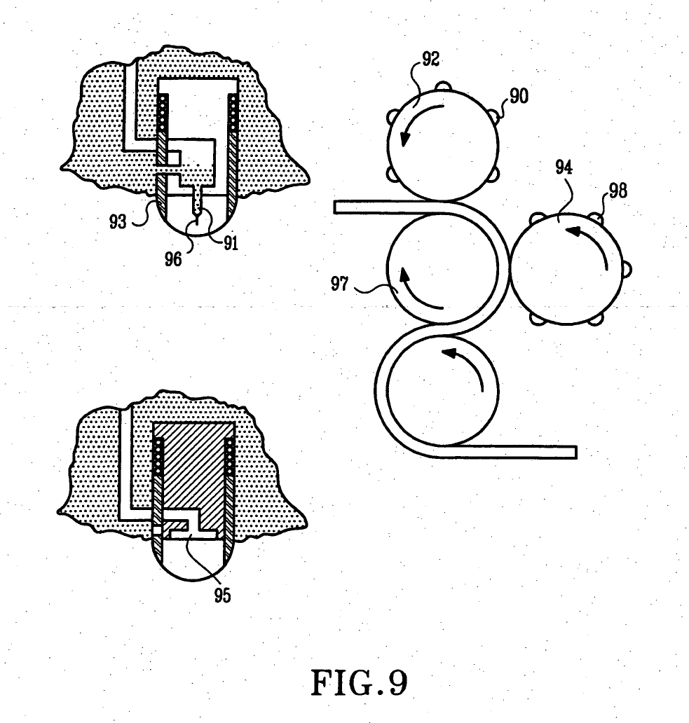

FIG. 9 illustrates the injection and sealing devices. The injection device comprises a nozzle 90 comprising an outlet 91 for electrolyte. The injection devices are arranged on a cylinder 92. In the Injector, the laminate is provided through two cylinders 92 and 97. The laminate presses up a radially displaceable cylinder 93, which is hollow and spring suspended. The injection needle 96 penetrates in the laminate at the same time as compressed electrolyte is supplied. Then the laminate passes another cylinder 94, which rotates synchronised to the first cylinder, and provides melted plastic on the injection points and seals the injection openings. The third cylinder sheets out the laminate, which also can cool the laminate. Instead of sealing by melt plastic, -sealing patches can be applied.

The final cell structure may be laminated onto a tensile stress resistant substrate, which may be flexible (e.g. made of glass-fibre or metal foil).

The sealing devices 98 arranged on a second cylinder 94 are of hot melt type and comprise an outlet 95 for delivering melt film to the section to be sealed.

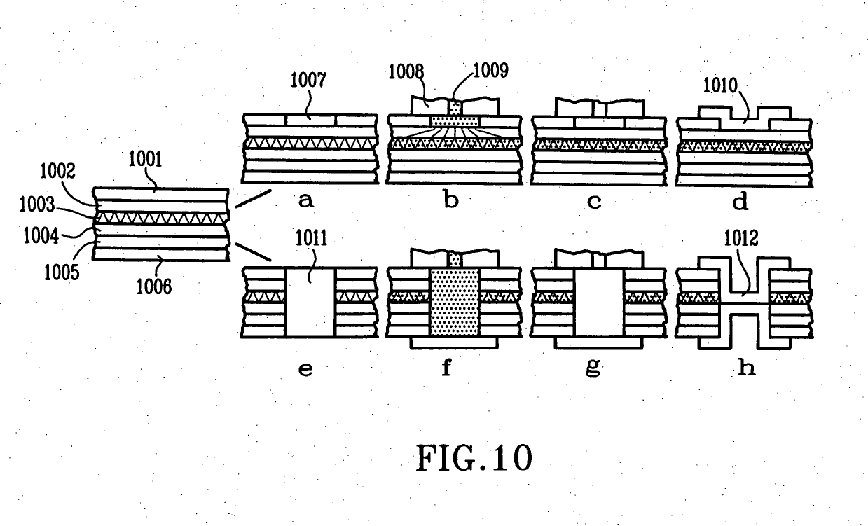

FIG. 10 illustrates two examples of injecting cells. Sequences a-d illustrate the first example and sequences e-h to the second example. The cell comprises the layers: bottom sealing film 1001, bottom electrode 1002, spacer 1003, substrate 1004, top electrode 1005 and top sealing film 1006.

According to the first example:
(a) A hole 1007 is arranged during the lamination in the bottom sealing film 1001,
(b) The injector 1008 injects under a pressure the electrolyte 1009 through the hole,
(c) The electrolyte penetrates the bottom electrode 1002 and fills the spacer 1003 and also some of the bottom electrode 1002 and the substrate 1004 due to capillary forces,
(d) A thin film 1010 is arranged over the hole and melted together with the film 1001.

According to the second example:
(e) A through hole 1011 is provided through the cell layers, e.g., through punching,
(f) The hole is filled under pressure with electrolyte,
(g) The electrolyte is distributed to the spacer (remaining electrolyte is removed from the hole),
(h) Sealing is provided with riveting or by thin films 1012 applied on each side of the laminate and scaled onto each other and onto the laminate surfaces.

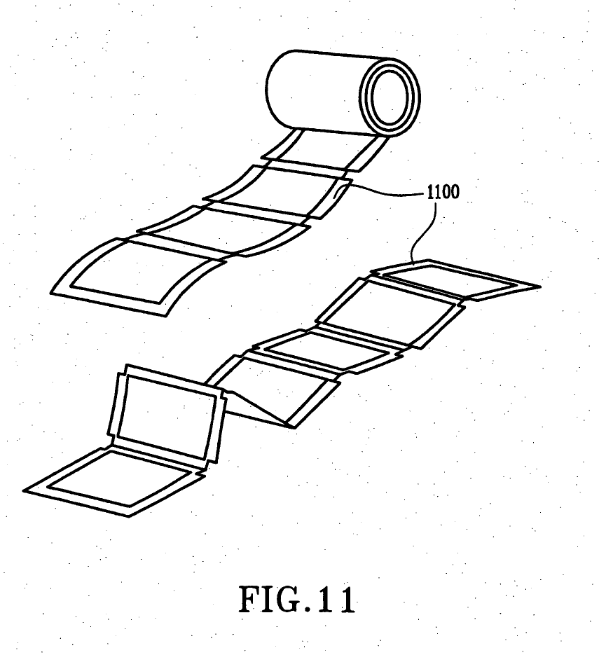

As it is illustrated in FIG. 11, the solar cell 1100 during the production can automatically be provided with “joints” allowing it to be folded or winded, which depends on the rigidity of the cells and joints. This allows simple transportation and storage. By folding and unfolding a number of cells it is possible to adjust the output voltage and/or current of a solar cell.

The electrical connection may be performed by applying conductive materials, such as foil, tape, wire or print on the outside of the physically connected cells, thereby electrically connecting the electrodes of the separate cells. The electric connections may be easily changeable/moveable, thereby changing the electric circuits. On the electric connections, conductive wires may be applied, in order to connect the cell-structure to the load to be supplied by electricity.

Earlier described process, refers to a single-lane based semi-material. It is also possible to produce a multi-lane based semi-material. By the method described as follows, it is possible to manufacture a very long “semi-material”, consisting of several, continuously connected “endless” cells, which are connected in series. Advantages with this multi-lane process compared to the previously described single-lane based process, is that the number of process steps are reduced, that a separate process step for contacting is avoided as contacting is automatically achieved as an integrated part in the process and that the “semi-material” easily can be produced in large rolls and thereafter be cut and sealed in cross-direction in suitable length. The filling of the cells will also be different. In the case of multi-lane process, the process-integrated series-connection means that the voltage level will be determined by the number of lanes, thereby it will not be adjustable in the same way as may be possible with the one-lane concept.

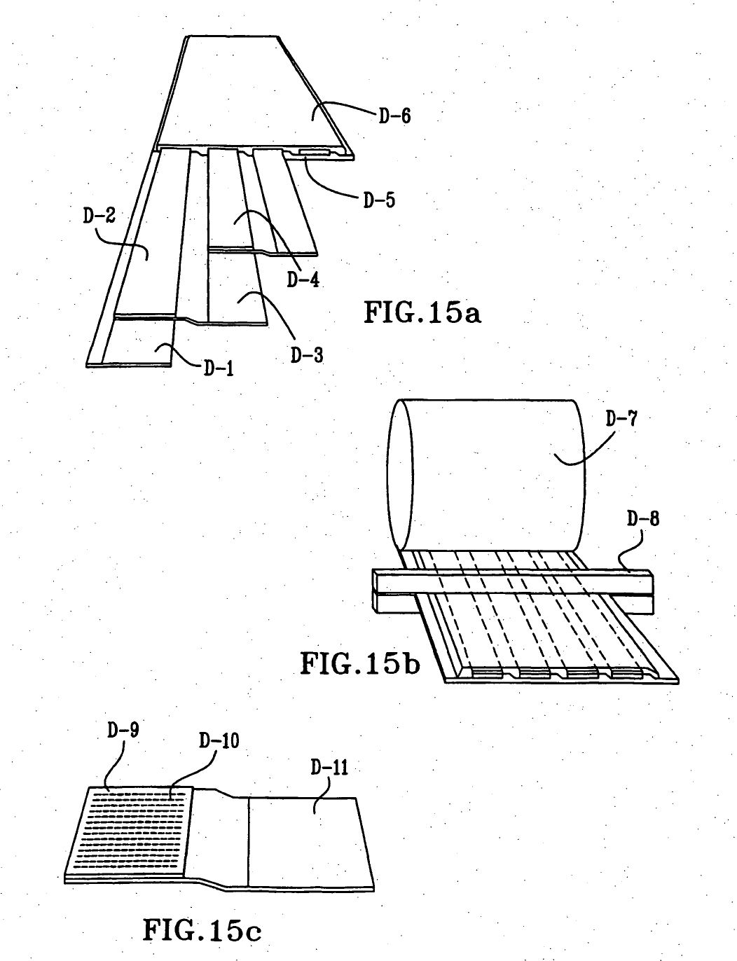

The multi-lane concept is schematically described in FIG. 15. The figure shows a flexible, conducting, and in most cases, heat-resistant substrate, which is continuously applied with semiconductor (such as TiO₂) on parts of the width and with catalyst on other parts of the width, keeping non-coated zones in-between (FIG. 15c), whereby it is possible to produce lanes which will function as upper electrode in one cell and at the same time as lower electrode in another cell (FIG. 15a), thereby automatically connecting one cell to another in series. Out from the process comes a laminate structure, which consists of one very long semi material with a few, very long cells connected in series (FIG. 15b). This laminate structure can be cut in pieces, the pieces can eventually be filled with electrolyte and heat-sealed in the cross-direction. Cutting of the laminate structure in pieces may also be done before encapsulation.

One example of the multi-lane process is described in the following:

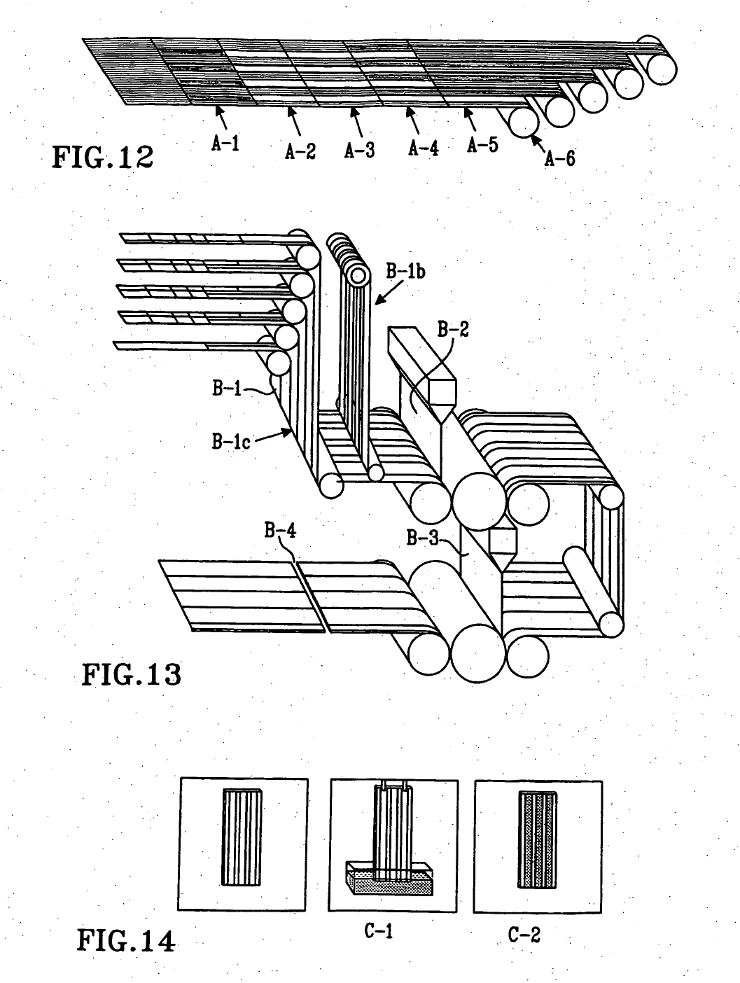

FIG. 12 (process step A) describes how a conducting and flexible substrate, preferably heat-resistant, such as metal-foil, is perforated continuously in machine-direction and partly in cross-direction (A-1). Thereafter the perforated areas are coated with semi-conductor, such as TiO2 (A-2) and sintered (A-3). Thereafter the catalyst is continuously applied on parts of the width (A-4) on a certain distance from the semi-conductor. The catalyst may also be applied before the semi-conductor. (If graphite is used as catalyst, the life-time of the catalyst is increased if it is exposed to heat during the application of the semi-conductor). Next step is the sensitisation with the dye (A-5), whereafter the substrate (e.g. metal-foil) is slitted into lanes (A-6). The process step A may also be performed on single lanes, already separated from each other before the application of semi-conductor and catalyst is done. The substrate (e.g. metal-foil) may be pre-coated with a thin polymer layer in order to simplify production. This layer will then “disappear” in the sintering step.

FIG. 13 (process step B) shows how the different lanes which are produced in process step A are overlapped (B-1), after which a “heat-protection-layer” (B-1b) and/or a spacer-layer (B-1c) can be laminated according to the drawing. Thereafter the overlapped lanes are encapsulated (B-2 and B-3) by extrusion coating or heat-lamination.

Thereafter the “semi-material” is cut into pieces of suitable length (8-4). The films, which constitute the encapsulation, can consist of a combination of polymers as earlier mentioned in the description of the single-lane concept. If extrusion coating is used for encapsulation, the edges can be made even with the method described in FIG. 8.

FIG. 14 (process step C) shows how the cells are filled without injection, namely by dipping them In an electrolyte bath, whereby the filling is being done by capillary forces (C-1). Thereafter the edges are sealed and the series-connected cells are finalized. FIG. 9 shows the complete production process. The electrolyte may also be added earlier in the process, e.g. as a gel.

As an alternative solution to the above described process for producing a laminate structure with cells in series, instead laminate-structures with a single cell may be produced, whereafter the laminate-structure is connected/joined with other laminate-structures, in order to form a laminate-structure consisting of cells connected in series.

FIG. 15 schematically illustrates the multi-lane laminate structure. In FIG. 15a, the overlapped and encapsulated lanes are shown. The first lane will constitute the lower electrode (D-1) of the first cell. The second lane will constitute the upper electrode (D-2) of the first cell and the lower electrode (D-3) of the second, cell. The third lane will constitute the upper electrode (D-4) of the second cell and the lower electrode of the third cell. The overlapped lanes are encapsulated by a lower polymer layer (D-5) and an upper polymer layer (D-6). FIG. 15b shows how the roll of continuous laminate (D-7), consisting of four cells in series, is cut and heat-sealed with a device (D-8) In suitable lengths. FIG. 15c shows the build-up of one lane. It consists of a flexible, heat resistant substrate, e.g. a metal foil (D-10), which is perforated underneath a layer of semi-conductor, e.g. TiO₂ (D-9) on one part of the surface and with a layer of catalyst (D-11) applied on the upper side on another part of the surface. Alternative build-ups of a lane may be a PET-film as a substrate, which is coated with ITO on the back-side, and with one part of the surface consisting of a layer of semi-conductor, e.g. TiO₂ on the back-side and one part of the surface consisting of catalyst on the back-side, this surface area being perforated. Yet another build-up of a lane may be a PET-film as a substrate, which is coated with ITO on the front-side, and with one part of the surface consisting of a layer of semi-conductor, e.g. TiO₂ on the front-side, this surface area being perforated and one part of the surface consisting of catalyst on the front-side. Yet another build-up of a lane may be a combination of the above, meaning that one part of the lane consists of a PET-film which is coated with ITO on the back-side after being partly joined with a metal-foil on the back-side, and with part of the PET-surface consisting of a layer of semi-conductor, e.g. TiO₂ on the back-side, and part of the metal-foil surface being covered with catalyst on the front-side.

The cell according to the invention can have many applications, but the flexibility and mobility allows also using it as emergency device, e.g. for charging car batteries, camping energy source etc.

As mentioned above, the invention suggests using as the semi-conducting layer a flexible, heat resistant substrate (i.e. glass fibre, (SiOₓ-coated) perforated metal), on which TiO₂ is applied. Thus, it is possible to sinter the TiO₂ at, e.g. 450° C., which is preferable with respect to function and efficiency. In contrary to prior art, the heat resistant substrate is not used as lower electrode, as this means that the electrolyte layer has to be applied partially between the semiconductor and the source of light, this decreasing efficiency.

Some advantages using metal-foil as electrodes are, except from the possibility to sinter the TiO₂ at high temperatures, to be able to avoid ITO as conducting layer and cost efficiency, also that conductivity is better than for ITO-coated PET, meaning that it is easier to produce cells with larger surface areas. In order to secure best functionality of the heat-resistant electrodes, the following may be done:

The upper electrode, which is perforated or will be perforated at some point during the production, may consist of a substrate of metal-foil, e.g. aluminium-foil, in order to be heat-resistant. On the upper side the semi-conductor, e.g. TiO₂ is applied. Between the metal-foil and the TiO₂, a thin layer of another metal may be applied by metallization or a thin layer of SnO₂ may be applied in order to avoid contact and thereby interaction between the metal-electrode and the electrolyte. Between the thin metal-layer or SnO₂-layer, a thin layer of SiO, may be applied in order to secure adhesion between layers. On the back-side of the metal-foil a thin SiOₓ-layer or a polymer layer may be applied in order to avoid direct contact between the electrodes and/or to avoid interaction between the electrolyte and the back-side of the upper electrode.

The lower electrode may consist of a substrate of metal-foil, e.g. aluminium-foil in order to be heat resistant. On the metal-foil a catalyst is applied, e.g. a thin layer of Pt or C. Between the metal-foil and the catalyst, a thin layer of SnO₂ may be applied. Between the SnO₂-layer and the metal-foil, a thin layer of SiOₓ may be applied.

The invention also suggests using as the electrode layers flexible, heat-resistant substrates (i.e. glass fibre screen, or (SiOₓ-coated) metal-screen), which are coated with TCO. As the substrates are heat-resistant, the TCO used can be SnO₂, which is preferred with respect to the functionality and efficiency.

The invention also suggests using one single substrate both as upper electrode and as the substrate for the semi-conducting layer. This may be done by first applying the TCO-layer (e.g. SnO2) on the substrate, thereafter applying the TiO2-layer on top of the TCO-layer.

The invention also suggests performing a second sealing/encapsulation operation with different sealing techniques, in order to further strengthen the seal around the cell.

The invention also suggests that heat resistant electrodes, e.g. consisting of perforated metal-foil or metal-screen may be metallized with a thin layer of another metal in order to be more “inert” towards the electrolyte.

The invention also suggests that polymer-based substrates may be metallized in order to achieve conductivity. They may be used as electrodes by perforation if used as upper electrode.

The invention also suggests that other carriers than gels may be used for the electrolyte. An electrolyte-impregnated spacer layer (e.g. paper or foamed polymer) may be laminated into cells used in applications in which adhesion between layers is not necessary. Hereby the injection step can be avoided.

Dye photovoltaic (dye-PV) cells generally have several advantages related to their application. Flexible Dye-PV cells specifically have several additional advantages. As the cells are coming out from the production process, they are “endlessly” physically connected to each other and possible to roll up on a roll. From this roll, end-products can be cut, consisting of several physically connected cells, which might be electrically connected in series or in parallel, depending on use. They might also be used as single cells. Thus, they are: suitable for light poor environment, such as indoors use or cloudy areas, rollable cells are obtained, flexibility of the cells allows easily foldable, easily transportable and easily storable end-products and they provide possibility to adjust at least one of current or voltage in a simple way.

Electrical connection can be performed by applying conductive materials, such as foil, tape, wire or print on the outside of the physically connected cells, thereby electrically connecting the electrodes of the separate cells, the electric connections being easily changeable/moveable, thereby changing the electric circuits and on the electric connections, conductive wires being applied, connecting the cell-structure to the load to be supplied by electricity.

The invention is not limited to the shown embodiments but can be varied in a number of ways without departing from the scope of the appended claims and the arrangement and the method can be implemented in various ways depending on application, functional units, needs and requirements etc. In some cases, for example, TCO can be applied through evaporation. Moreover, if semi-conducting material is used, it can be screen-printed on the substrate or the upper electrode.

1. A flexible photovoltaic element, comprising
at least two covering layers; and
a semi-material, comprising:
at least two electrode layers; and
at least one electrolyte carrier layer,
wherein the at least two covering layers and the semi-material are formed by at least one process selected from the group consisting of lamination and extrusion coating, and covering layers seal the semi-material.

2. The photovoltaic element of claim 1, further comprising at least one layer of substantially flexible and heat-resistant substrate.

3. The photovoltaic element of claim 2, wherein the substrate is provided with substantially semi-conducting characteristics, laminated in the semi-material.

4. The photovoltaic element of claim 1, wherein at least one of said electrode layers comprises of a polymeric material applied with a transparent conductive oxide.

5. The photovoltaic element of claim 3, wherein the substrate is applied with a semi-conducting material.

6. The photovoltaic element of claim 1, wherein at least one of the electrode layers consist of a screen structure applied with a semi-conducting material.

7. The photovoltaic element of claim 1, wherein at least one electrode layer comprises a substantially flexible and heat-resistant material applied with a semi-conducting material.

8. The photovoltaic element of claim 1, wherein at least one electrode layer comprises a wire-screen applied with a semi-conducting material.

9. The photovoltaic element according to claim 1, wherein at least one of the electrode layers is perforated.

10. The photovoltaic element according to claim 1, wherein one electrode layer is arranged as a bottom layer and applied with a catalyst.

11. The photovoltaic element of claim 5, wherein the semi-conducting material is applied with a dye.

12. The photovoltaic element according to claim 1, comprising a spacer structure arranged between the electrode layers.

13. The photovoltaic element of claim 3, wherein said polymeric material comprises at least one material selected from the group consisting of PE, PET, PP and PA.

14. The photovoltaic element of claim 8, wherein the substantially flexible and heat-resistant material comprises glass-fiber.

15. The photovoltaic element of claim 5, wherein the screen structure comprises glass-fiber or textile.

16. The photovoltaic element of claim 7, wherein the wire-screen comprises a conductive material.

17. The photovoltaic element of according to claim 4, wherein the transparent conductive oxide comprises SnO₂.

18. The photovoltaic element of according to claim 5, wherein the semi-conducting material comprises TiO₂.

19. The photovoltaic element of according to claim 1, wherein the at least one electrolyte carrier comprises electrolyte consisting of potassium iodine or an iodine solution.

20. The photovoltaic element of claim 1, comprising a layer of polymer coated with a transparent conductive oxide, a substrate provided with TiO₂ and a dye, a spacer provided with electrolyte and a layer of polymer coated with a transparent conductive oxide and catalyst.

21. The photovoltaic element of claim 1, wherein at least one of the covering layers is substantially transparent, and comprises a single-layer or a multi-layer structure, the simple-layer or multi-layer structure comprising at least one layer selected from the group consisting of PE-layer(s), PP-layer(s), PET-layer(s), tie-layer(s), ionomer layer(s), EAA-layer(s), EMAA-layer(s), PA-layer(s), EVOH-layer(s), SiOₓ, layer(s).

22. The photovoltaic element of claim 1, wherein the layers in the semi material and covering layers are provided with partial adhesion between all layers prior to application of covering layers and sealing.

23. The photovoltaic element of claim 1, further comprising at least two heat-resistant layers, two of the layers either comprising electrodes or a substrate for electrode layers, and at least one of the heat-resistant layers comprising a substrate for an at least one semi-conducting layer.

24. The photovoltaic element of claim 1, wherein at least one of the electrode layers is provided as a covering layer.

25. The photovoltaic element according to any of preceding claims claim 1, wherein the layers are supplied continuously before being processed.

26. The photovoltaic element according to claim 1, wherein the photovoltaic element is a Grätzel-cell.

27. The photovoltaic element according to claim 1, wherein an electrical connection is performed by applying conductive materials on external surface of the cells, thereby electrically connecting the electrodes of separate cells.

28. The photovoltaic element according to claim 1, wherein the electrodes comprise at least one form selected from the group consisting of perforated metal-foils and of metal-screens.

29. The photovoltaic element according to claim 1, wherein the substrate is polymer-based and metallized.

30. The photovoltaic element according to claim 20, wherein the electrolyte-impregnated spacer layer is laminated into cells.

31. The photovoltaic element according to claim 30, wherein the spacer consists of comprises paper or foamed polymer.

32. The photovoltaic element according to claim 2, wherein the flexible, heat resistant substrate is made of a metal foil, which is perforated underneath a layer of semi conductor on one part of a surface and with a layer of catalyst applied on an upper side on another part of the surface.

33. The photovoltaic element according to claim 1, wherein the substrate comprises a PET-film, which is coated with ITO on a first side, and with one part of its surface consisting of a layer of semi-conductor on the first side and one part of the surface consisting of catalyst on the first side, which surface area is perforated.

34. The photovoltaic element according to claim 1, wherein the substrate comprises a PET-film, which is coated with ITO on a front-side, and with one part of its surface consisting of a layer of semi-conductor on the front-side, which surface area is perforated and one part of the surface consisting of catalyst on the front-side.

35. The photovoltaic element according to claim 1, wherein one part of the substrate comprises a PET-film which is coated with ITO on a back-side after being partly joined with a metal-foil on the back-side, and with part of a PET-surface consisting of a layer of semi-conductor on the back-side, and part of the metal-foil surface being covered with catalyst on a front-side.

36. A method of producing a flexible photovoltaic element, the method comprising:
providing a semi-material comprising at least two electrode layers and at least one electrolyte carrier layer;
providing at least two covering layers;
joining together the at least two covering layers and the semi-material through at least one process selected from the group consisting of extrusion coating and lamination so that the covering layers seal the semi-material.

37. The method of claim 36, wherein the at least two covering layers, the electrode layers and at least one electrolyte carrier layer are supplied continuously.

38. The method of claim 36, further comprising providing at least one layer of a heat resistant substrate and/or a spacer layer before lamination.

39. The method of claim 36, further comprising providing the substrate with TiO₂.

40. The method of claim 38, further comprising an injecting an electrolyte in the electrolyte carrier layer.

41. The method of claim 38, wherein the substrate and/or a spacer layer is the electrolyte carrier.

42. The method of claim 36, further comprising cutting the cell structure into smaller cell units.

43. The method according to claim 36, wherein the electrode layers are produced in a second parallel process.

44. The method of claim 40, wherein injecting comprises:
arranging a hole during the lamination in a bottom sealing film,
injecting the electrolyte by an injector under a pressure the electrolyte through the hole, the electrolyte filling a spacer and some of the bottom electrode and the substrate due to capillary forces, and
arranging a thin film over the hole and melting it together with the film.

45. The method of claim 40, wherein injecting comprises:
providing a through hole (1011) through the cell layers.
filling said hole with electrolyte, which is distributed to the spacer, and
providing a sealing with riveting or by thin films applied on each side of the laminate.

46. The method according to claim 36, wherein each of the at least two covering layers are in the form of a film or foil.

47. The method of claim 38, wherein the substrate is rolled together with the heat-resistant spacer layer, which prevents contact between the rolled up substrate layers and allows for hot air to pass between the substrate layers.

48. The method of claim 47, wherein said the roll is exposed to hot air, where in drying and sintering of TiO₂ is performed.

49. The method of claim 36, wherein the element is produced in a multi-lane using a multi-lane based semi-material.

50. The method of claim 49, wherein the method comprises manufacturing long semi-material, consisting of several, continuously connected endless cells, which are connected in series.

51. The method of claim 50, wherein the method produces a flexible, conducting and heat-resistant substrate, by continuously applying with semiconductor on parts of the width and with catalyst on other parts of the width, keeping non-coated zones in-between, producing lanes functioning as an upper electrode in one cell and at the same time as a lower electrode in another cell.

52. The method of claim 51, characterised by automatically connecting one cell to another in series and producing a laminate structure.

53. The method of claim 52, wherein the laminate structure is cut in pieces, which are filled with electrolyte and heat-sealed in a cross-direction.

54. A multi-lane assembly line comprising:
a first lane for a lower electrode of a first cell,
a second lane for an upper electrode of a first cell and the lower electrode of a second cell,
a third lane for an upper electrode of the second cell and the lower electrode of a third cell,
overlapped lanes sealed by a lower polymer layer and an upper polymer layer, and
cut and heat-sealing device in suitable lengths.

55. A photovoltaic cell, comprising:
a first electrode;
a second electrode in the form of a screen; and
a photoactive layer between the first and mesh electrodes.

56. The photovoltaic cell of claim 55, wherein the photoactive layer comprises titanium dioxide.

57. A photovoltaic cell, comprising:
a first electrode;
a second electrode, the second electrode being perforated; and
a photoactive layer between the first and mesh electrodes.

58. The photovoltaic cell of claim 57, wherein the photoactive layer comprises titanium dioxide.
